(19) United States
(12) Patent Application Publication
(10) Pub. No.: US 2026/0312553 A1
(43) Pub. Date: Oct. 8, 2026

(54) AMPLIFIER CIRCUIT AND CHARGE SENSITIVE PREAMPLIFIER

(71) Applicant: OOKUMA DIAMOND DEVICE CO., LTD., Hokkaido (JP)

(72) Inventors: Hitoshi UMEZAWA, Hokkaido (JP); Yokkaido ITO, Hokkaido (JP); Takahiro YAMAGUCHI, Hokkaido (JP); Hiroyuki KAWASHIMA, Hokkaido (JP); Tatsuyuki MAEKAWA, Tokyo (JP)

(21) Appl. No.: 19/483,380

(22) PCT Filed: Apr. 17, 2024
(86) PCT No.: PCT/JP2024/015237

§ 371 Date: Nov. 11, 2025

(51) Int. Cl. H03F 3/45

(52) U.S. Cl. CPC H03F 3/45179

(57) ABSTRACT

Provided is a practical amplifier circuit that operates even in severe environments and a charge sensitive preamplifier using the amplifier circuit. Therefore, an amplifier circuit 10 includes a plurality of field effect transistors each of which is formed of a p-channel type and formed on a diamond substrate. The plurality of field effect transistors includes an amplifying transistor (Q1, Q2) that outputs an output current between a source and a drain according to an input voltage input between a gate and the source, and a load transistor (Q3) that converts the output current of the amplifying transistor into an output voltage. The amplifying transistor (Q1, Q2) includes a plurality of diamond transistors in which a source, a drain, and a gate are connected in common, and the load transistor (Q3) includes a current source in which a gate and a source are connected.

### CROSS-REFERENCE TO RELATED APPLICATIONS

This application is a National Stage application of International Patent Application No. PCT/JP2024/015237, filed on Apr. 17, 2024, which claims priority to Japanese Patent Application No. 2023-079526, filed May 12, 2023, each of which is hereby incorporated by reference in its entirety.

### TECHNICAL FIELD

The present invention relates to an amplifier circuit and a charge sensitive preamplifier, and relates to, for example, an amplifier circuit including a diamond field effect transistor (FET) and a charge sensitive preamplifier including the amplifier circuit.

### BACKGROUND

Patent Document 1 discloses a field effect transistor having high radiation resistance and circuit characteristics ensured. The field effect transistor includes a non-doped diamond layer having a hydrogen-terminated surface, a gate electrode formed on the hydrogen-terminated region via an insulating layer, and a source electrode and a drain electrode formed on both sides of the insulating layer via a p+ diamond layer. The field effect transistor can ensure transconductance of 0.5 mS/mm or more under room temperature conditions even after receiving X-ray irradiation of 5 MGy.

### RELATED ART DOCUMENT

### Patent Document

Patent Document 1: Japanese Patent Application Laid-open Publication No. 2022-104826

### SUMMARY

In recent years, there is an increasing demand for semiconductor devices that achieve stable operation in severe environments such as high radiation environments typified by nuclear reactors and aerospace fields, and high temperature environments typified by industrial machines and automobile fields. In severe environments, it is difficult for a general semiconductor element made of silicon to operate normally. For this reason, utilization of a wide band gap semiconductor has been widely studied. Among them, in particular, a diamond semiconductor has a strong bond, a large band gap, and thermal conductivity, and thus is expected as a material suitable for severe environments.

However, diamond semiconductors are currently only developed at an element level, and are not developed as practical circuits and systems. That is, circuits and systems that can be used in severe environments have not yet been obtained. As a part of the factors, a complementary circuit as in the case of silicon cannot be used, the amplification degree of the transistor alone is low, and the like.

Specifically, a p-channel type transistor having performance at a practical level can be achieved by, for example, a configuration as disclosed in Patent Document 1. However, it is difficult to achieve an n-channel type transistor having performance at a practical level. In addition, the amplification degree, that is, the transconductance of a transistor alone can be lower by several orders of magnitude than that in the case of silicon on the assumption of 0.5 mS/mm as disclosed in Patent Document 1, for example. As a result, it has been difficult to achieve a practical amplifier circuit, particularly an amplifier circuit having a high gain.

The present invention has been made in view of such circumstances, and an object thereof is to provide a practical amplifier circuit and a practical charge sensitive preamplifier that operate even in severe environments.

The foregoing and other objects and novel features of the present invention will become apparent from the description of the present specification and the accompanying drawings.

An outline of a representative embodiment of the invention disclosed in the present application will be briefly described below.

An amplifier circuit according to an embodiment includes a plurality of field effect transistors each of which is formed of a p-channel type and formed on a diamond substrate. The plurality of field effect transistors includes an amplifying transistor that outputs an output current between a source and a drain according to an input voltage input between a gate and the source, and a load transistor that converts the output current of the amplifying transistor into an output voltage. The amplifying transistor includes a plurality of diamond transistors in which a source, a drain, and a gate are connected in common, and the load transistor constitutes a current source when the gate and the source are connected.

When the effects obtained by the representative embodiment of the invention disclosed in the present application are briefly described, a practical amplifier circuit that operates even in severe environments can be achieved.

### BRIEF DESCRIPTIONS OF THE DRAWINGS

FIG. 1A is a cross-sectional view illustrating a device configuration example of a diamond FET used in an amplifier circuit according to an embodiment.

FIG. 1B is a diagram illustrating an example of electrical characteristics of the diamond FET illustrated in FIG. 1A.

FIG. 2 is a circuit diagram illustrating a configuration example of an amplifier circuit according to a first embodiment.

FIG. 3A is a waveform diagram illustrating an example of a voltage signal of each node in FIG. 2.

FIG. 3B is a waveform diagram illustrating an example of a voltage signal of each node in FIG. 2.

FIG. 4A is a diagram illustrating an example of electrical characteristics in a case where diamond transistors are connected in parallel.

FIG. 4B is a comparison target of FIG. 4A and a diagram illustrating an example of electrical characteristics of a diamond transistor alone.

FIG. 5 is a circuit diagram illustrating a configuration example of a charge sensitive preamplifier according to a second embodiment.

FIG. 6A is a waveform diagram illustrating an example of a voltage signal of each node in an amplifier circuit alone to which a negative feedback line is not added in FIG. 5.

FIG. 6B is a waveform diagram illustrating an example of a voltage signal of each node in an amplifier circuit alone to which a negative feedback line is not added in FIG. 5.

FIG. 7A is a Bode diagram illustrating an example of frequency characteristics observed at an input node of an amplification stage, which is a second stage, in FIG. 5.

FIG. 7B is a comparative example with respect to FIG. 7A and is a Bode diagram in a case where a phase compensation circuit is not provided.

FIG. 8A is a Bode diagram illustrating an example of frequency characteristics observed at an input node of an amplification stage, which is a third stage, in FIG. 5.

FIG. 8B is a comparative example with respect to FIG. 8A and is a Bode diagram in a case where a phase compensation circuit is not provided.

### DETAILED DESCRIPTION

Hereinafter, embodiments of the present invention will be described in detail with reference to the drawings. Note that, in all the drawings for describing the embodiments, the same members are denoted by the same reference numerals in principle, and repeated description thereof will be omitted.

### Regarding Diamond FET

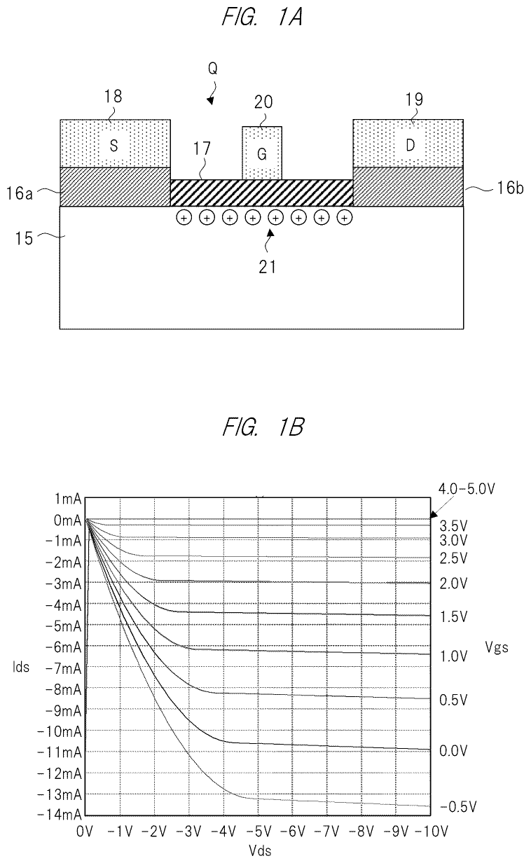

FIG. 1A is a cross-sectional view illustrating a device configuration example of a diamond FET used in an amplifier circuit according to an embodiment. FIG. 1A illustrates a p-channel type field effect transistor (FET) formed on a diamond substrate. In the specification, such a p-channel type field effect transistor is simply referred to as a diamond transistor Q. The diamond transistor Q illustrated in FIG. 1A includes a diamond substrate 15, p+ contact layers 16a and 16b, an insulating film 17, a source(S) electrode 18, a drain (D) electrode 19, and a gate (G) electrode 20.

The insulating film 17 is disposed on the diamond substrate 15 and has a film thickness of, for example, about 5 nm to 100 nm. The insulating film 17 is made of, for example, aluminum oxide (Al₂O₃), calcium fluoride (CaF₂), magnesium fluoride (MgF₂), silicon dioxide (SiO₂), silicon nitride (Si₃N₄), or the like. The gate (G) electrode 20 is disposed on the diamond substrate 15 via the insulating film 17.

The p+ contact layers 16a and 16b are disposed on both sides of the insulating film 17 on the diamond substrate 15, and have a film thickness of, for example, about 20 nm to 300 nm. The p+contact layers 16a and 16b are formed by injecting boron (B) having a predetermined concentration into a diamond material. The source(S) electrode 18 is disposed on the diamond substrate 15 via the p+ contact layer 16a, which is one of the p+ contact layers. The drain (D) electrode 19 is disposed on the diamond substrate 15 via the p+ contact layer 16b, which is the other of the p+ contact layers.

The source (S) electrode 18, the drain (D) electrode 19, and the gate (G) electrode 20 are made of, for example, gold (Au), ruthenium (Ru), aluminum (Al), titanium (Ti), molybdenum (Mo), copper (Cu), chromium (Cr), lead (Pb), zinc (Zn), platinum (Pt), or a combination thereof. The film thickness of each electrode is, for example, about 10 nm to 100 nm.

In such a configuration, hole carriers are accumulated on the surface of the diamond substrate 15 by hydrogen termination. The accumulation of hole carriers forms a two-dimensional electron gas layer (2DEG), in other words, a channel 21, on the surface of the diamond substrate 15. In addition, a depletion layer is formed in the channel 21, and the thickness of the depletion layer changes according to a gate-source voltage Vgs. As a result, the concentration of the two-dimensional electron gas and eventually the magnitude of a drain-source current Ids can be controlled by the gate-source voltage Vgs.

FIG. 1B is a diagram illustrating an example of electrical characteristics of the diamond FET illustrated in FIG. 1A. FIG. 1B illustrates a state in which the characteristic of the drain-source current Ids with respect to a drain-source voltage Vds changes depending on the gate-source voltage Vgs. The diamond transistor Q illustrated in FIG. 1A has a normally-on characteristic, in other words, a depletion type characteristic. Therefore, as illustrated in FIG. 1B, even when the gate-source voltage Vgs is 0 V, a negative drain-source current Ids flows by applying a negative drain-source voltage Vds. That is, by applying a negative voltage to the drain with reference to the source, a current flows from the source to the drain.

In addition, the diamond transistor Q illustrated in FIG. 1A is of a p-channel type. Therefore, as illustrated in FIG. 1B, the drain-source current Ids approaches zero as a positive gate-source voltage Vgs increases, and a negative drain-source current Ids increases as a negative gate-source voltage Vgs increases. That is, the drain-source current Ids approaches zero as a large positive voltage is applied to the gate with reference to the source, and a large current flows from the source to the drain as a large negative voltage is applied to the gate with reference to the source. In the example of FIG. 1B, when the gate-source voltage Vgs exceeds about 4 V, the drain-source current Ids becomes zero.

Here, the diamond material can be operated at a high temperature of, for example, about 5 times and a high voltage of about 30 times, and has thermal conductivity of about 20 times as high as that of the silicon material. Therefore, for example, a circuit including the diamond transistor Q as illustrated in FIG. 1A is expected to be used in severe environments where the silicon material cannot provide sufficient resistance. However, when the circuit is constituted by the diamond transistor Q, for example, there is a unique constraint different from a case where the circuit is constituted by a silicon FET such as a MOSFET. As an example, it is difficult to achieve an n-channel type diamond transistor instead of the p-channel type diamond transistor Q as illustrated in FIG. 1A at a practical level.

For this reason, when a circuit is constituted by the diamond transistor Q, a complementary circuit configuration combining a p-channel type and an n-channel type, which is common in a MOSFET or the like, cannot be applied, and various contrivances are necessary. Therefore, it is advantageous to use an amplifier circuit described in each embodiment described below and various element techniques included in the amplifier circuit. Note that the configuration of the diamond transistor Q is not limited to the configuration example illustrated in FIG. 1A, and it is sufficient if the configuration is at least a p-channel type field effect transistor formed on a diamond substrate.

### First Embodiment

### Configuration and Operation of Amplifier Circuit

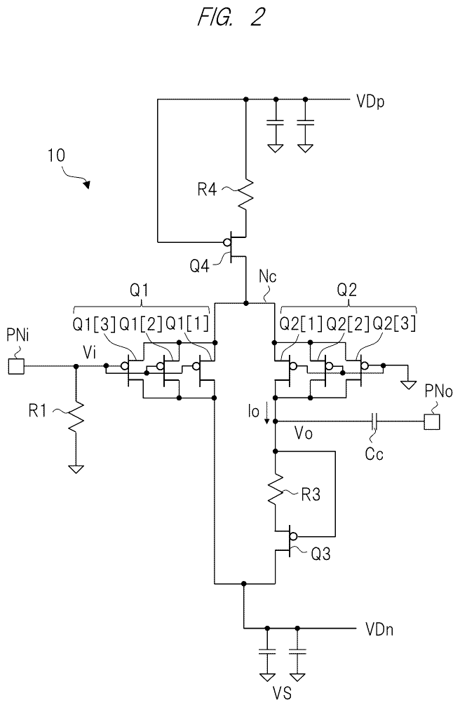

FIG. 2 is a circuit diagram illustrating a configuration example of an amplifier circuit according to a first embodiment. An amplifier circuit 10 illustrated in FIG. 2 includes diamond transistors Q1 to Q4, resistive elements R1, R3, and R4, and a coupling capacitor Cc. The diamond transistor Q4 is a bias transistor, and supplies a bias current to the diamond transistors Q1 and Q2 in parallel. A power supply voltage on a high potential side, here, a positive electrode power supply voltage VDp is supplied to a source of the diamond transistor Q4. The diamond transistor Q4 constitutes a current source when a gate and the source are connected, specifically, by being connected via the resistive element R4 connected to the source. The current value of the current source is set based on the resistance value of the resistive element R4.

A power supply voltage on a low potential side, here, a negative electrode power supply voltage VDn is supplied to a drain of the diamond transistor Q1. A source of the diamond transistor Q1 is connected to a drain of the diamond transistor Q4 and a source of the diamond transistor Q2 via a common node Nc. In addition, the bias current from the diamond transistor Q4 is divided and supplied to the sources of the diamond transistors Q1 and Q2.

The diamond transistors Q1 and Q2 are amplifying transistors constituting a differential pair of a differential amplifier circuit. In this case, the diamond transistor Q4 constitutes a tail current source of the differential amplifier circuit, and serves as a tail transistor that supplies a tail current to the diamond transistors Q1 and Q2. In addition, the diamond transistor (first transistor) Q1 and the diamond transistor (second transistor) Q2 constitute a common-source amplifier circuit in the differential amplifier circuit.

Here, the diamond transistor Q1 includes a plurality of, here, three diamond transistors Q1[1], Q1[2], and Q1[3] in which a source, a drain, and a gate are connected in common. Similarly, the diamond transistor Q2 also includes a plurality of, here, three diamond transistors Q2[1], Q2[2], and Q2[3] in which a source, a drain, and a gate are connected in common. As described above, the diamond transistors Q1 and Q2 constituting the differential pair desirably include the same number of diamond transistors having uniform characteristics in order to maintain differential balance, in other words, to equalize electrical characteristics.

The diamond transistor Q1 inputs an input voltage Vi from an input terminal PNi to the gate thereof. The drain current of the diamond transistor Q1 changes according to a change in the input voltage Vi. In this example, since it is not necessary to convert the drain current into a voltage and output the voltage, the drain of the diamond transistor Q1 is fixed to the negative electrode power supply voltage VDn.

On the other hand, a change in the drain current of the diamond transistor Q1 is transmitted as a change in the drain current of the diamond transistor Q2 via the source of the diamond transistor Q2 while balancing with the sink amount of the constant current from the diamond transistor Q4. At this time, by the action of the constant current source constituted by the diamond transistor Q4, a current whose increasing/decreasing direction is opposite is input to the source of the diamond transistor Q2 at the same amount as the change amount of the drain (source) current generated in the diamond transistor Q1. Note that the sum of the drain (source) current values of the diamond transistors Q1 and Q2 is always equal to the current value of the constant current source by the diamond transistor Q4.

The diamond transistor Q2 here has the gate to which a reference power supply voltage VS, here a ground power supply voltage (0 V) is supplied. Therefore, a voltage is not input to the gate of the diamond transistor Q2, and a current corresponding to that in which the increase/decrease in current change generated in the diamond transistor Q1 is inverted is input to the source of the diamond transistor Q2. As a result, a drain current corresponding to the opposite direction of the change in the drain current in the diamond transistor Q1 flows through the diamond transistor Q2. The drain current forms an output current Io between the source and the drain of the diamond transistor Q2.

The negative electrode power supply voltage VDn is supplied to a drain of the diamond transistor Q3. As in the case of the diamond transistor Q4, the diamond transistor Q3 constitutes a current source when a gate and a source are connected, specifically, by being connected via the resistive element R3 connected to the source. The current value of the current source is set based on the resistance value of the resistive element R3.

Further, the current source constituted by the diamond transistor Q3 functions as a current source load that converts the output current Io into an output voltage Vo by being connected to the drain of the diamond transistor Q2. That is, the diamond transistor Q3 is a load transistor that converts the output current Io of the amplifying transistor (Q1, Q2) into the output voltage Vo. Note that, technically, the output current Io is converted into the output voltage Vo by an equivalent resistance value of the current source load.

The coupling capacitor Cc blocks a direct-current component from the output voltage Vo of the diamond transistor Q3 and allows an alternating-current component to pass therethrough. The alternating-current component of the output voltage Vo is output to an output terminal PNo via the coupling capacitor Cc. The resistive element R1 is connected between the gate of the diamond transistor Q1 and the reference power supply voltage VS. The resistive element R1 is, for example, a high resistive element having a resistance value at an M ohm level, and sets a bias point of the gate voltage of the diamond transistor Q1 to the reference power supply voltage VS.

Note that each element illustrated in FIG. 2, that is, the transistor, the resistive element, and the capacitor is formed as an integrated circuit on a common diamond substrate, or mounted on a wiring substrate as a discrete component and connected on the wiring substrate, for example. Alternatively, regarding each element illustrated in FIG. 2, some elements are formed as an integrated circuit on a common diamond substrate, and some other elements are constituted by discrete components. In this case, the integrated circuit and the discrete components are mounted on the wiring substrate and connected on the wiring substrate.

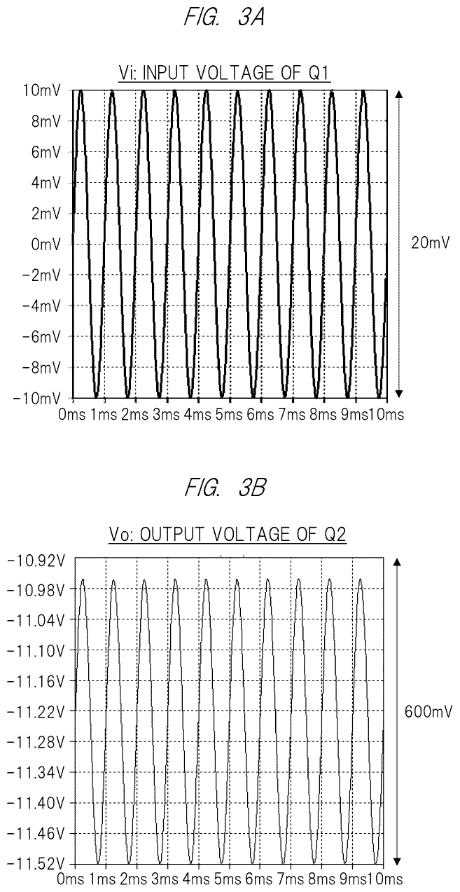

FIGS. 3A and 3B are waveform diagrams illustrating an example of a voltage signal of each node in FIG. 2. FIG. 3A illustrates the input voltage Vi input to the gate of the diamond transistor Q1. FIG. 3B illustrates the output voltage Vo output from the drain of the diamond transistor Q2. Note that, in this example, the positive electrode power supply voltage VDp in FIG. 2 is +24 V, and the negative electrode power supply voltage VDn is −24 V.

First, as illustrated in FIG. 3A, a sine wave signal having an amplitude of 20 m V and a cycle of 1 ms, that is, a frequency of 1 kHz, in other words, an alternating-current voltage is applied as the input voltage Vi to the gate of the diamond transistor Q1. The alternating-current voltage changes around the reference power supply voltage VS of 0 V. The diamond transistor Q1 outputs a drain (source) current based on transconductance (gm) or the like according to the input voltage Vi.

The output current Io having a change amount that is the same as the change amount of the drain current generated in the diamond transistor Q1 and in the opposite direction flows through the drain of the diamond transistor Q2. Then, the output current Io from the diamond transistor Q2 is converted into the output voltage Vo as illustrated in FIG. 3B by the diamond transistor Q3, which is a load transistor. As illustrated in FIG. 3B, the output voltage Vo is a sine wave signal having an amplitude of about 570 m V and having the same phase as the input voltage Vi illustrated in FIG. 3A.

As described above, a gain of about 29 (~570 m V/20 mV) times is obtained as the amplifier circuit 10 by the differential amplifier circuit including the diamond transistors Q1 to Q4. Note that the direct-current component of the output voltage Vo is determined by dividing the direct-current component of a common source node Nc of the diamond transistors Q1 and Q2 (direct-current component of the output voltage Vc) and the negative electrode power supply voltage VDn by the diamond transistors Q2 and Q3 or the like, and is about −11.22 V in this example.

### Regarding Various Element Techniques

### Regarding Circuit Topology

The amplifier circuit 10 illustrated in FIG. 2 constitutes the differential amplifier circuit using the two diamond transistors Q1 and Q2 as a differential pair. In addition, each of the two diamond transistors Q1 and Q2 functions as a common-source amplifier circuit. However, as illustrated in FIG. 2, when a load resistor is not provided on the diamond transistor Q1 side, from a different point of view, the diamond transistor (first transistor) Q1 can be regarded as a transistor constituting a common-drain circuit, in other words, a source follower circuit.

On the other hand, since a fixed voltage is applied to the gate of the diamond transistor (second transistor) Q2, the diamond transistor Q2 can be regarded as a transistor constituting a common-gate amplifier circuit from a different point of view. In this case, the diamond transistor Q4 functions as a bias transistor that supplies a bias current to the diamond transistors Q1 and Q2. In addition, the diamond transistor Q3 functions as a load transistor constituting a common-gate amplifier circuit.

As described above, the amplifier circuit 10 can be regarded as a combination of a common-drain circuit and a common-gate amplifier circuit from a different point of view. In this case, the diamond transistor Q1 outputs an output voltage having substantially the same amplitude and the same phase as the input voltage Vi from the source according to the input voltage Vi input to the gate. The diamond transistor Q2 inputs the output voltage of the diamond transistor Q1 to the source, and outputs the output current Io between the source and the drain according to transconductance (gm) or the like.

However, in understanding the circuit design and the circuit operation, it is easy to understand them as an orthodox circuit configuration, that is, by considering them as a common-source amplifier circuit. In this case, the diamond transistor Q1 constituting the common-source amplifier circuit can receive the input voltage Vi with high input impedance, and converts a change in the input voltage into a change in the drain current. In the example of FIG. 2, since an output signal is not taken out from the drain side of the diamond transistor Q1, the load resistor that is usually provided for converting a change in current into a change in voltage is omitted.

On the other hand, a change in the drain current in the diamond transistor Q1 is transmitted to the diamond transistor Q2 whose gate is grounded in such a manner that the direction of the change is inverted. The total sum of the drain currents flowing through the diamond transistor Q1 and the diamond transistor Q2 is always constant and is equal to the current value discharged from the constant current source constituted by the diamond transistor Q4.

Here, when a signal is taken out from the drain of the diamond transistor Q1, a current change is taken out as a voltage change by providing a load of a resistive element or a virtual high resistance load by a constant current source that can be an alternative thereto. In this case, the Miller effect is generated in which the value of a parasitic capacitance between the input and the output, that is, the parasitic capacitance (Cgd) between the gate and the drain is effectively multiplied by the gain. Then, the frequency characteristics are deteriorated by the Miller effect, and for example, the frequency characteristics of the amplifier circuit may be distorted.

In particular, in the diamond FET, the parasitic capacitance may be larger than that of the MOSFET, and the effect of the Miller effect may become more remarkable. Therefore, particularly in the first stage of the amplifier circuit, as illustrated in FIG. 2, it is advantageous to take out the output from the drain of the diamond transistor Q2 whose gate is grounded. In other words, it is advantageous to take out the output via the diamond transistor Q2 constituting the common-gate amplifier circuit. In principle, the Miller effect does not occur in the common-gate amplifier circuit. This makes it possible to enhance frequency characteristics.

In addition, in a general transistor amplifier circuit, in order to reduce the effect of the Miller effect, cascode connection in which the source of a transistor whose gate is grounded is connected to the drain of a transistor whose source is grounded is often used. However, in the cascode connection, the voltage range that the output voltage can take may be narrowed as a result of the vertical stacking of transistors.

Therefore, here, the transistor whose source is grounded is not provided in a vertically stacking manner with respect to the diamond transistor Q2 whose gate is grounded, but the diamond transistor Q1 whose drain is grounded is provided in a horizontally stacking manner. Then, interference with another external circuit connected to the input terminal PNi is suppressed by high input impedance of the diamond transistor Q1 constituting the common-drain circuit.

### Regarding Coupling Capacitor

For example, when a MOSFET or the like is used, the bias voltage of each transistor can be relatively easily set by forming a complementary circuit in which a p-channel type and an n-channel type are combined. On the other hand, when the diamond transistor Q is used, it is necessary to form a circuit only of a p-channel type, and thus it is not easy to appropriately set the bias voltage of each diamond transistor Q. Therefore, here, the coupling capacitor Cc for alternating-current coupling of the output voltage Vo is provided. The bias voltage is set by applying a fixed voltage via a high resistive element (R1) or the like. Accordingly, the amplifier circuit 10 functions not as an amplifier circuit for direct current but as an amplifier circuit for alternating current.

### Regarding Parallel Connection of Diamond Transistors

With the diamond transistor Q, the transconductance (gm) may be lower by several orders of magnitude than that of a MOSFET or the like. Therefore, in an amplifier circuit in which a high gain is demanded, contrivances for improving the gain are necessary. Therefore, the amplifying transistor (Q1, Q2) includes a plurality of diamond transistors Q1[1] to Q1[3] and Q2[1] to Q2[3] connected in parallel. Specifically, the amplifying transistor is configured by connecting diamond transistors Q having the same device configuration and transistor size (gate length, gate width) in parallel.

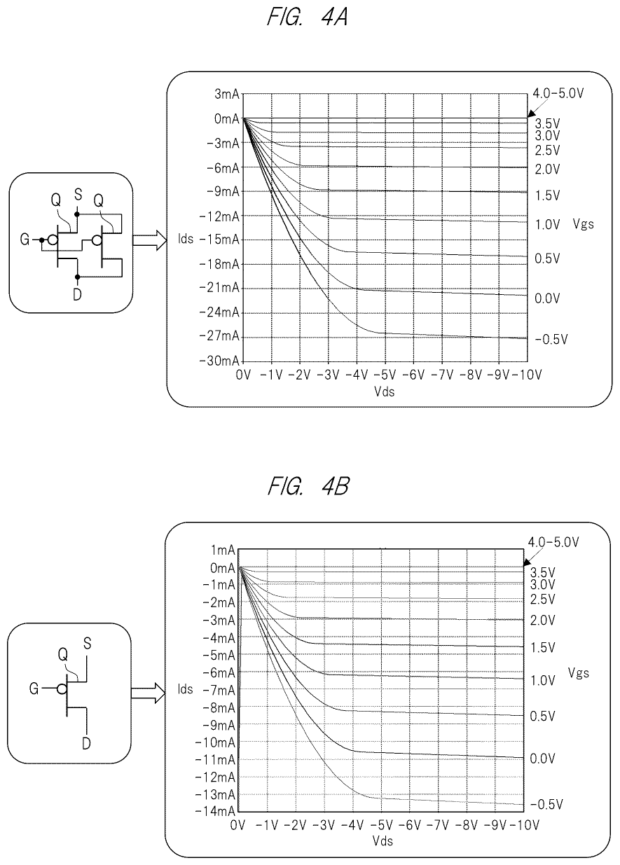

FIG. 4A is a diagram illustrating an example of electrical characteristics in a case where diamond transistors are connected in parallel. FIG. 4B is a comparison target of FIG. 4A and a diagram illustrating an example of electrical characteristics of a diamond transistor alone. FIG. 4B illustrates the same electrical characteristics as in FIG. 1B. For example, when the gate-source voltage Vgs is 0 V and the drain-source voltage Vds is −10 V, the drain-source current Ids is about −11 mA. On the other hand, in the example of FIG. 4A, by connecting two diamond transistors Q in parallel, when the gate-source voltage Vgs is 0 V and the drain-source voltage Vds is −10 V, the drain-source current Ids becomes about −22 mA, that is, twice.

As described above, by using the parallel connection of the diamond transistors Q, the transconductance (gm) can be effectively increased to N times according to the number of parallels N. Note that, as a method for increasing the amplification degree, the cascode connection described above, Darlington connection in a bipolar transistor, and the like are known. However, these methods increase the amplification degree by multiplying each transconductance (gm), but as described above, these methods narrow the voltage range of the output voltage, and also cause complication of the circuit.

Therefore, here, as a method of easily increasing the amplification degree, parallel connection of the diamond transistors Q is used. At this time, it is also possible to easily equalize the electrical characteristics of the diamond transistors Q1 and Q2 constituting the differential pair. Specifically, for example, it is sufficient if the plurality of diamond transistors Q is formed in a matrix on the same diamond substrate and parallel connection is achieved using the plurality of diamond transistors Q formed on the same diamond substrate.

Since the plurality of diamond transistors Q formed on the same diamond substrate usually has equivalent electrical characteristics, the electrical characteristics of the diamond transistors Q1 and Q2 can be made uniform by constituting the diamond transistors Q1 and Q2 using these transistors. More specifically, when the amplifier circuit 10 is achieved by an integrated circuit, for example, it is sufficient if the diamond transistors Q corresponding to the number of parallel connections formed on the diamond substrate are wired by a wiring layer or the like on the diamond substrate.

On the other hand, in a case where the amplifier circuit 10 is achieved by a discrete component, for example, it is sufficient if the plurality of diamond transistors Q formed on the same diamond substrate is individually diced, and then the diamond transistors Q corresponding to the number of parallel connections are mounted in one package. In this case, the diamond transistors Q corresponding to the number of parallel connections are wired in the package. Note that, in the example of FIG. 2, the number of parallel connections is three, but it is needless to say that the number is not limited to three, and it is sufficient if the number is the number according to the demanded amplification degree. In addition, when the demanded amplification degree is low, it is not always necessary to use parallel connection.

### Regarding Current Source

For example, it is conceivable to use a resistive element, which is a passive element, instead of an active element such as the load transistor (Q3) constituting the current source load or the bias transistor (Q4) constituting the current source. However, the resistive element can generate more noise than when the diamond transistor Q is used. In particular, when a resistive element is used instead of the load transistor, a resistive element having a high resistance value is required to increase the gain, so that more noise can be generated. In addition, since the direct-current bias point also moves due to this resistance value, circuit design under the two constraints of the gain and the direct-current bias is required, and the degree of difficulty of circuit design increases.

Therefore, here, the load transistor (Q3) and the bias transistor (Q4) constituting the current source are used. As a result, an equivalently high load resistor can be achieved without greatly affecting the direct-current bias, and noise generation and the like due to the high resistive element can also be suppressed. Note that since the resistive elements R3 and R4 for adjusting the current value included in the current source are set to low resistance values, the noise due to this is at a negligible level.

Further, by using the load transistor (Q3) constituting the current source load, frequency characteristics may be improved as compared with the case of using a resistive element. Specifically, for example, when a resistive element is used instead of the load transistor (Q3), the parasitic capacitance may be larger than when the load transistor (Q3) is used. On the other hand, when the load transistor (Q3) is used, the cutoff frequency can be increased by reducing the parasitic capacitance, and as a result, the amplifier circuit 10 can have a wide band.

### Main Effects of First Embodiment

As described above, the amplifier circuit 10 according to the first embodiment mainly includes the amplifying transistor (Q1, Q2) configured by parallel connection of the diamond transistors Q and the load transistor (Q3) constituting the current source load. As a result, a practical amplifier circuit that operates even in severe environments can be achieved. In addition, the amplifier circuit 10 includes the transistor (Q1) constituting the common-drain circuit and the transistor (Q2) constituting the common-gate circuit, and further includes the coupling capacitor Cc. As a result, a more practical amplifier circuit can be achieved.

### Second Embodiment

### Regarding Charge Sensitive Preamplifier

For example, when measuring radiation or the like, a charge sensitive preamplifier is used. The charge sensitive preamplifier converts a charge (current signal) according to the intensity of radiation output from a detector into a voltage signal by integrating the charge. The charge sensitive preamplifier is configured by an integrator, and specifically, is configured by adding a negative feedback path including an external load (resistive element and capacitor) to an amplifier circuit.

Such a charge sensitive preamplifier is required to have an open gain of, for example, 1000 times to several tens of thousands times or a wide bandwidth in addition to achieving a stable operation in severe environments. For example, in a case where the open gain is low, parasitic resistances and parasitic capacitances parasitic in circuit elements and wirings affect, and there arises a problem that the gain cannot be determined only by the external load, and eventually, the measurement accuracy of the radiation decreases. Therefore, it is advantageous to construct a charge sensitive preamplifier using the amplifier circuit 10 described in the first embodiment and various element techniques included in the amplifier circuit 10.

### Configuration and Operation of Charge Sensitive Preamplifier

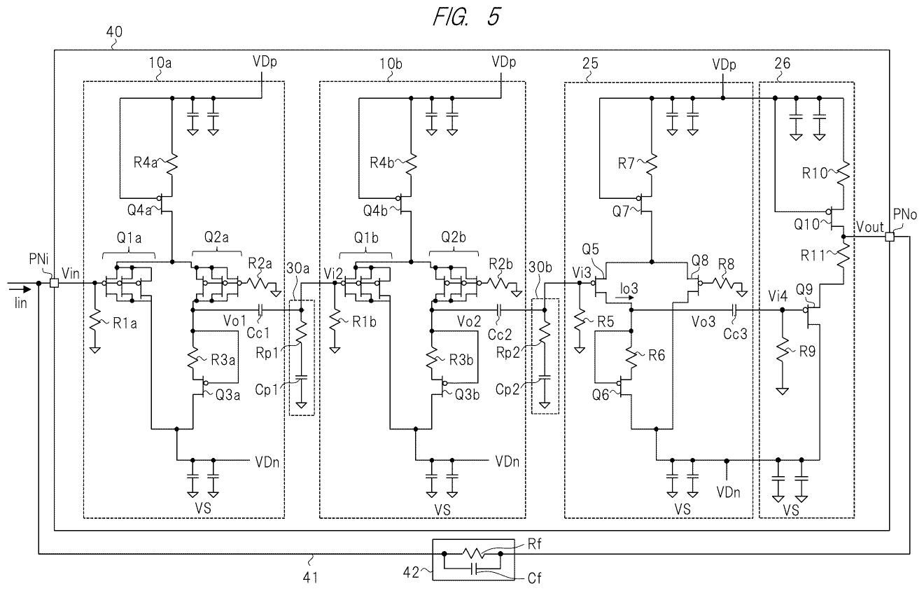

FIG. 5 is a circuit diagram illustrating a configuration example of a charge sensitive preamplifier according to a second embodiment. The charge sensitive preamplifier illustrated in FIG. 2, in other words, the integrator includes an amplifier circuit 40, a negative feedback line 41 added to the amplifier circuit 40, and an external load 42 inserted into the negative feedback line 41. The amplifier circuit 40 includes a plurality of (three in this example) cascade-connected amplification stages 10a, 10b, and 25, an output stage 26 provided at a subsequent stage of the amplification stage 25, and phase compensation circuits 30a and 30b. Each of the amplification stages 10a and 10b has substantially the same configuration as the amplifier circuit 10 illustrated in FIG. 2.

Specifically, the amplification stage 10a includes diamond transistors Q1a to Q4a, resistive elements R1a, R2a, R3a, and R4a, and a coupling capacitor Cc1. Similarly to the diamond transistors Q1 and Q2 illustrated in FIG. 2, each of the diamond transistors Q1a and Q2a includes three diamond transistors connected in parallel. However, in this example, unlike the diamond transistor Q2 illustrated in FIG. 2, a gate of the diamond transistor Q2a is connected to a reference power supply voltage VS via the resistive element R2a having a low resistance value. Other configurations are similar to those in the case of FIG. 2.

The amplification stage 10a inputs an input voltage Vin from an input terminal PNi to a gate of the diamond transistor Q1a, and outputs an output voltage Vo1 from a drain of the diamond transistor Q2a. The coupling capacitor Cc1 allows an alternating-current component of the output voltage Vo1 to pass as an input voltage Vi2 to the amplification stage 10b.

Similarly to the amplification stage 10a, the amplification stage 10b includes diamond transistors Q1b to Q4b, resistive elements R1b, R2b, R3b, and R4b, and a coupling capacitor Cc2. Each of the diamond transistors Q1b and Q2b includes three diamond transistors connected in parallel. A gate of the diamond transistor Q2b is connected to a reference power supply voltage VS via the resistive element R2b having a low resistance value.

The amplification stage 10b inputs the input voltage Vi2 from the coupling capacitor Cc1 in the amplification stage 10a to a gate of the diamond transistor Q1b, and outputs an output voltage Vo2 from a drain of the diamond transistor Q2b. The coupling capacitor Cc2 allows an alternating-current component of the output voltage Vo2 to pass as an input voltage Vi3 to the amplification stage 25.

On the other hand, the amplification stage 25 includes diamond transistors Q5 to Q8, resistive elements R5 to R8, and a coupling capacitor Cc3. Similarly to the diamond transistors Q4a and Q4b, the diamond transistor Q7 is a bias transistor or a tail transistor, and supplies a bias current or a tail current to the diamond transistors Q5 and Q8. A positive electrode power supply voltage VDp is supplied to a source of the diamond transistor Q7. The diamond transistor Q7 constitutes a current source, for example, a tail current source when the gate and the source are connected, specifically, by being connected via the resistive element R7 connected to the source. The current value of the current source is set based on the resistance value of the resistive element R7.

In the diamond transistor Q8, a reference power supply voltage VS is supplied to a gate through the resistive element R8 having a low resistance value, and a negative electrode power supply voltage VDn is supplied to a drain. A source of the diamond transistor Q8 is connected to a drain of the diamond transistor Q7 and a source of the diamond transistor Q5. The sources of the diamond transistors Q5 and Q8 are connected in common to constitute a differential pair of a differential amplifier circuit.

The input voltage Vi3 from the coupling capacitor Cc2 of the amplification stage 10b is input to a gate of the diamond transistor Q5. The diamond transistor Q5 is an amplifying transistor and is also a transistor constituting a common-source amplifier circuit. The diamond transistor Q5 outputs an output current Io3 between the source and the drain according to the input voltage Vi3 input between the gate and the source.

A negative electrode power supply voltage VDn is supplied to a drain of the diamond transistor Q6. The diamond transistor Q6 constitutes a current source when a gate and a source are connected, specifically, by being connected via the resistive element R6 connected to the source. The current value of the current source is set based on the resistance value of the resistive element R6.

Further, the current source constituted by the diamond transistor Q6 functions as a current source load that converts the output current Io3 into an output voltage Vo3 by being connected to the drain of the diamond transistor Q5. That is, the diamond transistor Q6 is a load transistor that converts the output current Io3 of the amplifying transistor (Q5) into the output voltage Vo3. Note that, technically, the output current Io3 is converted into the output voltage Vo3 by an equivalent resistance value of the current source load.

As described above, the diamond transistor Q5, which is an amplifying transistor, constitutes a common-source amplifier circuit together with the diamond transistor Q6, which is a load transistor. The coupling capacitor Cc3 allows an alternating-current component of the output voltage Vo3 of the diamond transistor Q5 to pass as an input voltage Vi4 of the output stage 26. The resistive element R5 is connected between the gate of the diamond transistor Q5 and a reference power supply voltage VS. The resistive element R5 is, for example, a high resistive element having a resistance value at an M ohm level, and sets a bias point of the gate voltage of the diamond transistor Q5 to the reference power supply voltage VS.

The output stage 26 includes diamond transistors Q9 and Q10 and resistive elements R9 to R11, and outputs an output voltage Vout of the amplifier circuit 40 to an output terminal PNo. The diamond transistor Q10 is a bias transistor, and supplies a bias current to the diamond transistor Q9. A positive electrode power supply voltage VDp is supplied to a source of the diamond transistor Q10. The diamond transistor Q10 constitutes a current source when the gate and the source are connected, specifically, by being connected via the resistive element R10 connected to the source. The current value of the current source is set based on the resistance value of the resistive element R10.

The negative electrode power supply voltage VDn is supplied to a drain of the diamond transistor Q9. A source of the diamond transistor Q9 is connected to the drain of the diamond transistor Q10 via the resistive element R11. As a result, a bias current from the diamond transistor Q10 is supplied to the source of the diamond transistor Q9.

The diamond transistor Q9 is a transistor constituting a common-drain circuit, and inputs the input voltage Vi4 from the coupling capacitor Cc3 of the amplification stage 25 to a gate. Then, the diamond transistor Q9 outputs an output voltage from the source according to the input voltage Vi4 input to the gate. The output voltage is output as the output voltage Vout of the amplifier circuit 40 from the output terminal PNo via the resistive element R11.

As described above, the diamond transistor Q9 constitutes a common-drain circuit, in other words, a source follower circuit together with the diamond transistor Q10 constituting a current source. The resistive element R9 is connected between the gate of the diamond transistor Q9 and a reference power supply voltage VS, and sets a bias point of the gate voltage of the diamond transistor Q9 to the reference power supply voltage VS. The resistive element R11 is provided to adjust the direct-current level of the output voltage Vout.

The phase compensation circuits 30a and 30b are provided between a preceding stage and a subsequent stage of the plurality of amplification stages 10a, 10b, and 25. Here, the phase compensation circuit 30a is provided between the output of the amplification stage 10a and the input of the amplification stage 10b, and specifically, is provided between the coupling capacitor Cc1 and the gate of the diamond transistor Q1b. The phase compensation circuit 30b is provided between the output of the amplification stage 10b and the input of the amplification stage 25, and specifically, is provided between the coupling capacitor Cc2 and the gate of the diamond transistor Q5.

For example, the phase compensation circuit 30a performs pole-zero compensation using a resistive element Rp1 and a capacitor Cp1 connected in series between the gate of the diamond transistor Q1b and the reference power supply voltage VS. Similarly, the phase compensation circuit 30b also performs pole-zero compensation using a resistive element Rp2 and a capacitor Cp2 connected in series between the gate of the diamond transistor Q5 and the reference power supply voltage VS.

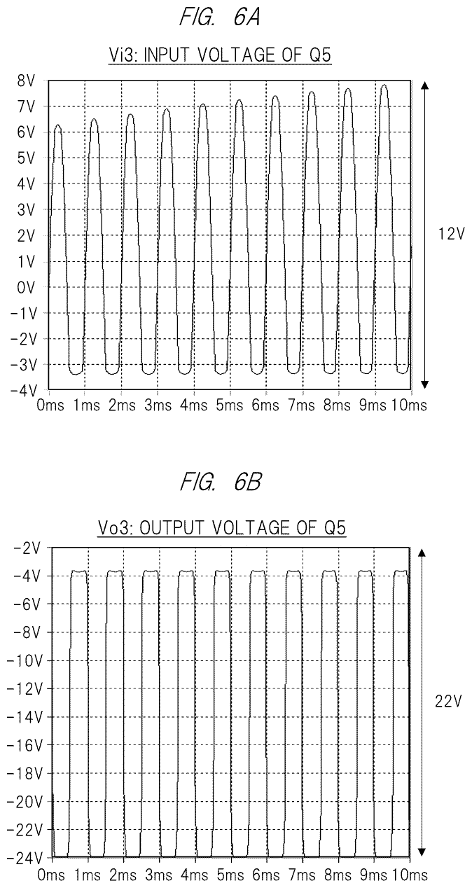

FIGS. 6A and 6B are waveform diagrams illustrating an example of a voltage signal of each node in an amplifier circuit alone to which a negative feedback line is not added in FIG. 5. FIG. 6A illustrates the input voltage Vi3 input to the gate of the diamond transistor Q5 in the amplification stage 25. FIG. 6B illustrates the output voltage Vo3 output from the drain of the diamond transistor Q5 in the amplification stage 25. In this example, the positive electrode power supply voltage VDp in FIG. 5 is +24 V, and the negative electrode power supply voltage VDn is −24 V. In addition, the input voltage Vin from the input terminal PNi is a sine wave signal having an amplitude of 20 m V and a cycle of 1 ms, that is, a frequency of 1 kHz, similarly to the case of FIG. 3A.

First, the amplification stage 10a is set to a gain of about 30 times, for example, and outputs the output voltage Vol having an amplitude of about 600 m V as illustrated in FIG. 3B. Subsequently, the amplification stage 10b is set to a gain of about 16 times, for example, and amplifies the amplitude of about 600 m V to an amplitude of about 10 V as illustrated in FIG. 6A. Next, the diamond transistor Q5 in the amplification stage 25 inputs the input voltage Vi3 having an amplitude of about 10 V as illustrated in FIG. 6A to the gate, and outputs the output voltage Vo3 having an amplitude of about 20 V as illustrated in FIG. 6B from the drain.

The diamond transistor Q5 is a transistor constituting a common-source amplifier circuit. In addition, unlike the amplification stages 10a and 10b, the differential amplifier circuit constituting the amplification stage 25 is configured to take out not the positive output but the negative output. Therefore, as illustrated in FIG. 6B, a sine wave signal having a phase opposite to the input voltage Vi3 is output as the output voltage Vo3 from the drain of the diamond transistor Q5. Thereafter, the output voltage Vo3 is transmitted to the output terminal PNo via the coupling capacitor Cc3 and the source follower circuit in the output stage 26. As a result, the output voltage Vout having the same phase and an equivalent amplitude as the output voltage Vo3 is output from the output terminal PNo.

In this case, the gain of the amplifier circuit 40 is about 1000 times (=20 V/20 mV). In addition, the gain of the common-source amplifier circuit including the diamond transistor Q5 is set to about twice. As described above, in a case where only a low gain is demanded, the diamond transistors Q5 and Q8, which are transistors constituting a differential pair and are also amplifying transistors, may be configured as a single body as illustrated in the example of FIG. 5. On the other hand, when a high gain is demanded, it is sufficient if parallel connection as illustrated in FIG. 4A is applied to the diamond transistors Q5 and Q8.

In addition, in this example, since a high gain is not demanded for the amplification stage 25, which is the final stage, unlike the amplification stages 10a and 10b, which are the first stage and the second stage, there is no particular problem even when the negative output is taken out. That is, even when the negative output is taken out, the effect of the Miller effect can be relatively reduced by the low gain. Further, in this example, the amplification stages 10a and 10b take out the positive output, and the amplification stage 25 takes out the negative output, so that the amplifier circuit 40 functions as an inverting amplifier. In other words, the input terminal PNi connected to the gate of the diamond transistor Q1a functions as an inverting input terminal.

The negative feedback line 41 negatively feeds back the output terminal PNo at which the output of the amplifier circuit 40 is generated to the input terminal PNi connected to the gate of the diamond transistor Q1a, that is, an inverting input terminal. The external load 42 is inserted into the negative feedback line 41 and includes a resistive element Rf and a capacitor Cf connected in parallel.

In such a charge sensitive preamplifier, in other words, an integrator, the input terminal PNi inputs a current signal Iin from a detector, which is not illustrated, for example, a current signal corresponding to the intensity of radiation. The capacitor Cf in the external load 42 is charged by the current signal Iin, specifically, a part of the current signal Iin.

On the other hand, when the gain of the amplifier circuit 40 is sufficiently high, the voltage of the external input terminal PNi can be regarded as the same as the reference power supply voltage VS, which is the gate voltage of the diamond transistor Q2a, that is, a virtual short circuit on the basis of negative feedback. As a result, the output voltage Vout generated at the output terminal PNo becomes equal to the charging voltage of the capacitor Cf based on the reference power supply voltage VS, that is, 0 V. In this manner, the gain at the time of integrating the total amount of input charges and converting into a voltage is determined by the capacitor Cf in the external load 42, and the resistive element Rf in the external load 42 is provided to adjust the decay time constant of the integrator.

### Regarding Various Element Techniques

### Regarding Plurality of Amplification Stages

As described in the first embodiment, with the diamond transistor Q, the transconductance (gm) may be lower by several orders of magnitude than that of a MOSFET or the like. In addition, cascode connection or the like may be difficult to apply to the diamond transistor Q. Therefore, in order to increase the gain of the entire amplifier circuit, it is advantageous to provide a plurality of cascade-connected amplification stages 10a, 10b, and 25 as illustrated in FIG. 5.

### Regarding Phase Compensation Circuit

However, when the plurality of amplification stages 10a, 10b, and 25 is provided, the phase delay increases. In particular, in a case where an amplifier circuit having a high gain is configured using a plurality of amplification stages, when a negative feedback circuit as illustrated in FIG. 5 is constructed using the amplifier circuit, positive feedback, that is, oscillation may occur due to a phase delay. Therefore, as illustrated in FIG. 5, it is advantageous to provide the phase compensation circuits 30a and 30b between a preceding stage and a subsequent stage of the plurality of amplification stages.

For example, the resistance value of the resistive element Rp1 and the capacitance value of the capacitor Cp1 in the phase compensation circuit 30a are set to values such that pole generated in the amplification stage 10a is cancelled by zero points generated by the resistive element Rp1 and the capacitor Cp1. Similarly, the resistance value of the resistive element Rp2 and the capacitance value of the capacitor Cp2 in the phase compensation circuit 30b are set to values such that pole generated in the amplification stage 10b is cancelled by zero points generated by the resistive element Rp2 and the capacitor Cp2.

Note that various configurations are known for the circuit configuration of the phase compensation circuit, and the configuration is not particularly limited to the configuration illustrated in FIG. 5. However, in the case of using the diamond transistor Q, the number of amplification stages tends to increase as compared with the case of using a MOSFET or the like, and eventually, a large phase delay tends to occur. Therefore, it is desirable to use pole-zero compensation that the pole is cancelled by a zero point instead of using a phase compensation method in which the frequency of the pole is simply reduced, that is, only a capacitor is added.

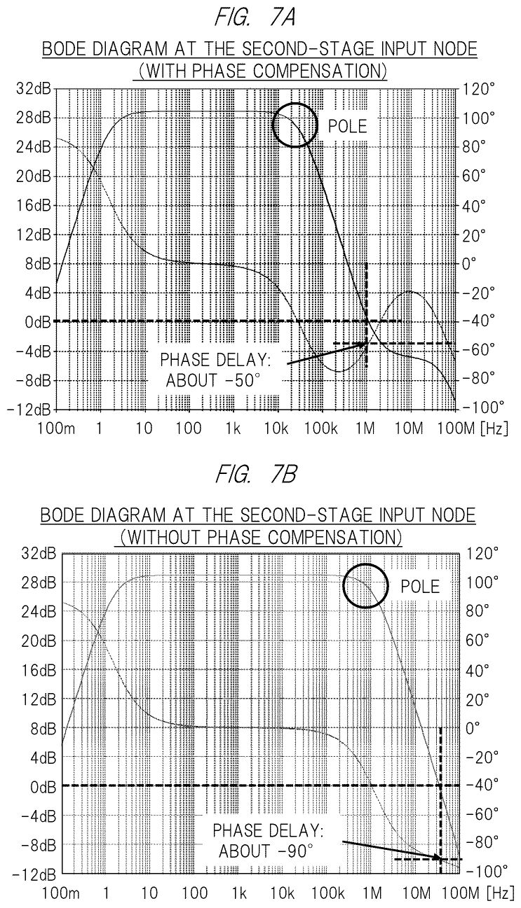

FIG. 7A is a Bode diagram illustrating an example of frequency characteristics observed at an input node (node of the input voltage Vi2) of the amplification stage 10b, which is a second stage, in FIG. 5. FIG. 7B is a comparative example with respect to FIG. 7A and is a Bode diagram in a case where the phase compensation circuit 30a is not provided. In a case where the phase compensation circuit 30a is not provided, as illustrated in FIG. 7B, a pole is generated in the vicinity of 1 MHz, and the phase delay when the gain is 0 dB is about −90°. On the other hand, when the phase compensation circuit 30a is provided, as illustrated in FIG. 7A, the pole is shifted to around several tens of kHz, and the phase delay is reduced by the zero point, so that the phase delay when the gain is 0 dB can be reduced to about −50°.

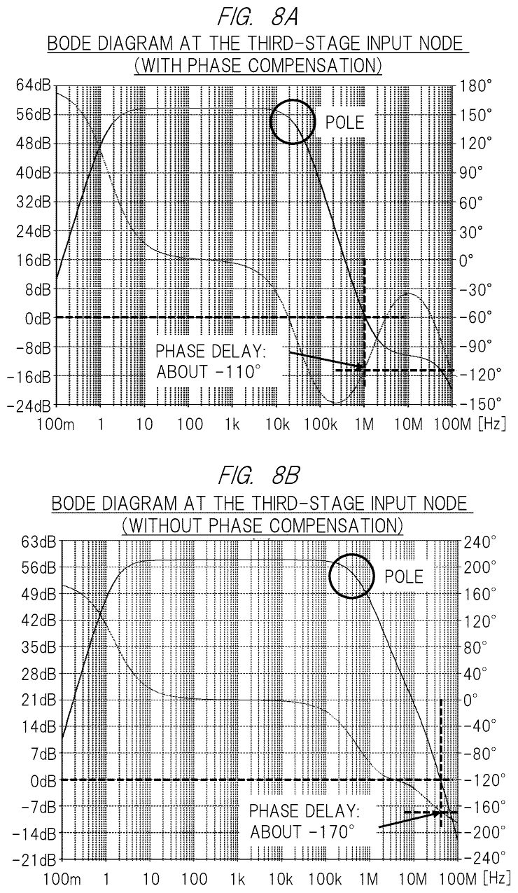

FIG. 8A is a Bode diagram illustrating an example of frequency characteristics observed at an input node (node of the input voltage Vi3) of the amplification stage 25, which is a third stage, in FIG. 5. FIG. 8B is a comparative example with respect to FIG. 8A and is a Bode diagram in a case where the phase compensation circuits 30a and 30b are not provided. In a case where both the phase compensation circuits 30a and 30b are not provided, as illustrated in FIG. 8B, a pole is generated in the vicinity of several hundred kHz, and the phase delay when the gain is 0 dB is about −170°. On the other hand, when both the phase compensation circuits 30a and 30b are provided, as illustrated in FIG. 8A, the pole is shifted to around several tens of kHz, and the phase delay is reduced by the zero point, so that the phase delay when the gain is 0 dB can be reduced to about −110°.

### Regarding Output Stage

In FIG. 5, the common-source amplifier circuit constituting the amplification stage 25, which is the third stage, has a high output impedance. In addition, even if a common-gate amplifier circuit is used instead of the common-source amplifier circuit, the output impedance increases. In a case where the output impedance of the amplifier circuit is high, for example, when an external load is connected, an error occurs in the value of the output voltage of the amplifier circuit. Therefore, in the example of FIG. 5, the output stage 26 including a source follower circuit is provided. As a result, the output impedance of the amplifier circuit 40 can be reduced.

### Main Effects of Second Embodiment

As described above, also by using the amplifier circuit 40 according to the second embodiment, effects similar to the various effects described in the first embodiment can be obtained. In addition, in the amplifier circuit 40 according to the second embodiment, the plurality of amplification stages 10a, 10a, and 25 and the output stage 26 including a source follower circuit are provided, and further, the phase compensation circuits 30a and 30b are provided. As a result, a practical amplifier circuit having a high gain can be achieved. Further, it is possible to construct a practical charge sensitive preamplifier using the amplifier circuit.

Although the invention made by the present inventor has been specifically described above on the basis of the embodiments, the present invention is not limited to the above-described embodiments, and various changes may be made without departing from the gist of the present invention. For example, the above-described embodiments have been described in detail in order to describe the present invention in an easy-to-understand manner, and are not necessarily limited to those having all the described configurations. In addition, a part of the configuration of a certain embodiment can be replaced with the configuration of another embodiment, and the configuration of another embodiment can be added to the configuration of a certain embodiment. In addition, it is possible to add, delete, and replace other configurations for a part of the configuration of each embodiment.

What is claimed is:

1. An amplifier circuit comprising: a plurality of field effect transistors each of which is formed of a p-channel type and formed on a diamond substrate,
wherein the plurality of field effect transistors includes
an amplifying transistor that outputs an output current between a source and a drain according to an input voltage input between a gate and the source, and
a load transistor that converts the output current of the amplifying transistor into an output voltage,
wherein the amplifying transistor includes a plurality of diamond transistors in which a source, a drain, and a gate are connected in common, and
wherein the load transistor constitutes a current source when a gate and a source are connected.

2. The amplifier circuit according to claim 1, comprising:
a first transistor and a second transistor in which a source is connected in common and constituting a differential pair of a differential amplifier circuit as the amplifying transistor,
wherein a number of the plurality of diamond transistors constituting the first transistor is equal to a number of the plurality of diamond transistors constituting the second transistor.

3. The amplifier circuit according to claim 2,
wherein the plurality of field effect transistors further includes a tail transistor having a drain connected to a source of the first transistor and a source of the second transistor, and
wherein the tail transistor constitutes a tail current source of the differential amplifier circuit when a gate and a source are connected.

4. The amplifier circuit according to claim 2,
wherein the first transistor inputs an alternating-current voltage that changes around a reference power supply voltage to a gate, and
wherein the reference power supply voltage is supplied to a gate of the second transistor.

5. The amplifier circuit according to claim 1,
wherein the amplifying transistor is a transistor constituting a common-gate amplifier circuit.

6. The amplifier circuit according to claim 1, further comprising:
a coupling capacitor that blocks a direct-current component from an output voltage of the load transistor and allows an alternating-current component to pass therethrough.

7. The amplifier circuit comprising: a plurality of field effect transistors each of which is formed of a p-channel type and formed on a diamond substrate,
wherein the plurality of field effect transistors includes
a first transistor that outputs an output voltage from a source according to an input voltage input to a gate and constitutes a common-drain circuit,
a second transistor that outputs an output current between a source and a drain using the output voltage of the first transistor as an input and constitutes a common-gate amplifier circuit,
a load transistor that converts the output current of the second transistor into an output voltage, and
a bias transistor that supplies a bias current to the first transistor and the second transistor,
wherein the second transistor includes a plurality of diamond transistors in which a source, a drain, and a gate are connected in common, and
wherein each of the load transistor and the bias transistor constitutes a current source when a gate and a source are connected via a resistive element connected to the source.

8. The amplifier circuit according to claim 7,
wherein a drain of the bias transistor is connected to the source of the first transistor and the source of the second transistor.

9. The amplifier circuit according to claim 8,
wherein the first transistor includes a same number of diamond transistors as the diamond transistors of the second transistor in which a source, a drain, and a gate are connected in common.

10. The amplifier circuit according to claim 7, further comprising:
a coupling capacitor that blocks a direct-current component from an output voltage of the load transistor and allows an alternating-current component to pass therethrough.

11. The amplifier circuit comprising: a plurality of cascade-connected amplification stages,
wherein each of the plurality of amplification stages includes a plurality of field effect transistors each of which is formed of a p-channel type and formed on a diamond substrate,
wherein the plurality of field effect transistors included in each of the plurality of amplification stages includes
an amplifying transistor that outputs an output current between a source and a drain according to an input voltage input between a gate and the source, and
a load transistor that converts the output current of the amplifying transistor into an output voltage,
wherein the amplifying transistor includes a plurality of diamond transistors in which a source, a drain, and a gate are connected in common, and
wherein the load transistor constitutes a current source when a gate and a source are connected.

12. The amplifier circuit according to claim 11, further comprising:
an output stage that is provided at a subsequent stage of the plurality of amplification stages and outputs an output voltage of the amplifier circuit,
wherein the output stage includes a plurality of field effect transistors each of which is formed of a p-channel type and formed on a diamond substrate,
wherein the plurality of field effect transistors included in the output stage includes
a common-drain transistor that outputs an output voltage from a source according to an input voltage input to a gate, and
a bias transistor that supplies a bias current to the common-drain transistor, and
wherein the bias transistor constitutes a current source when a gate and a source are connected.

13. The amplifier circuit according to claim 11, further comprising:
a coupling capacitor that is provided between a preceding stage and a subsequent stage of the plurality of amplification stages, blocks a direct-current component from an output voltage of the preceding stage and allows an alternating-current component to pass therethrough as an input voltage to the subsequent stage.

14. The amplifier circuit according to claim 11, further comprising:
a phase compensation circuit that is provided between a preceding stage and a subsequent stage of the plurality of amplification stages and performs pole-zero compensation using a resistive element and a capacitor.

15. The amplifier circuit according to claim 12,
wherein a first amplification stage of the plurality of amplification stages includes
a first transistor and a second transistor in which a source is connected in common and constituting a differential pair of a differential amplifier circuit as the amplifying transistor, and
a number of the plurality of diamond transistors constituting the first transistor is equal to a number of the plurality of diamond transistors constituting the second transistor.

16. The amplifier circuit according to claim 15,
wherein the first amplification stage further includes, as the plurality of field effect transistors, a tail transistor having a drain connected to a source of the first transistor and a source of the second transistor, and
wherein the tail transistor constitutes a tail current source of the differential amplifier circuit when a gate and a source are connected.

17. The amplifier circuit according to claim 15,
wherein the first transistor inputs an alternating-current voltage that changes around a reference power supply voltage to a gate, and
wherein the reference power supply voltage is supplied to a gate of the second transistor.

18. A charge sensitive preamplifier comprising:
the amplifier circuit according to claim 12;
a negative feedback line that is added to the amplifier circuit; and
an external load that is inserted into the negative feedback line and includes a resistive element and a capacitor.

19. The charge sensitive preamplifier comprising:
the amplifier circuit according to claim 15;
a negative feedback line; and
an external load that is inserted into the negative feedback line and includes a resistive element and a capacitor,
wherein a gate of the first transistor included in the first amplification stage is an inverting input terminal of the amplifier circuit,
wherein a reference power supply voltage is supplied to a gate of the second transistor included in the first amplification stage, and
wherein the negative feedback line negatively feeds back an output of the amplifier circuit to the inverting input terminal.
